(19) United States
(12) Patent Application Publication
(10) Pub. No.: US 2024/0170550 A1
(43) Pub. Date: May 23, 2024

(54) SEMICONDUCTOR DEVICE

(71) Applicant: SONY SEMICONDUCTOR SOLUTIONS CORPORATION, KANAGAWA (JP)

(72) Inventor: NAOKI KAKOIYAMA, KANAGAWA (JP)

(21) Appl. No.: 18/552,200

(22) PCT Filed: Jan. 24, 2022
(86) PCT No.: PCT/JP2022/002332

§ 371 Date: Sep. 25, 2023

(30) Foreign Application Priority Data
Apr. 5, 2021 (JP) 2021-064449

(51) Int. Cl. H01L 29/423; H01L 27/088; H01L 29/778

(52) U.S. Cl. CPC H01L 29/42356; H01L 27/088; H01L 29/778

(57) ABSTRACT

A semiconductor device according to one embodiment the disclosure includes multiple transistors coupled in parallel to each other. Each of the transistors includes a gate electrode, a source electrode, and a drain electrode that extend in a first direction. The plurality of gate electrodes provided one by one to each of the transistors are arranged at a predetermined interval in a second direction crossing the first direction such that the following expressions (1) and (2) are satisfied:

Xi≤Xi+1 (1)

X1<Xn (2)

where Xi represents a center position coordinate of an i-th gate electrode of the gate electrodes in the first direction, Xi+1 represents a center position coordinate of an i+1th gate electrode of the gate electrodes in the first direction, and n represents number of the gate electrodes.

### TECHNICAL FIELD

The disclosure relates to a semiconductor device.

### BACKGROUND ART

The fifth generation (5G) mobile communication system is assumed to use signals in millimeter bands. The millimeter bands, in which spatial attenuation is large, require high-power output, resulting in the need for high-power, high-frequency semiconductor devices. Examples of the high-power, high-frequency semiconductor devices include power amplifiers and RF switches.

Incidentally, the high output, high-frequency semiconductor devices have problems of heat generation due to Joule heat. As the temperature of a channel increases, the electrical resistance of the channel and peripheral wiring lines increases, resulting in deterioration in device characteristics. In particular, when channels are dense, suppressing the concentration of heat generation leads to a decrease in a maximum temperature. Therefore, for example, the inventions described in Patent Literatures 1 and 2 propose to suppress the concentration of heat generation by making the arrangement of fingers into a zigzag or V-shape.

### CITATION LIST

### Patent Literature

PTL 1: International Publication No. WO2018/02549
PTL 2: Japanese Unexamined Patent Application Publication No. H7-283235

### SUMMARY OF THE INVENTION

However, as described in PTLs 1 and 2, when the array of fingers is made into a zigzag or V-shape, a semi-closed region surrounded by the fingers becomes a dead space. Such dead space reduces the degree of freedom of the circuit layout, hindering a reduction in size. It is thus desirable to provide a semiconductor device with a multi-finger structure that makes it possible to suppress the concentration of heat generation while suppressing an increase in size without reducing the degree of freedom of the circuit layout.

A semiconductor device according to one embodiment of the disclosure includes multiple transistors coupled in parallel to each other. Each of the transistors includes a gate electrode, a source electrode, and a drain electrode that extend in a first direction. The plurality of gate electrodes provided one by one to each of the transistors is arrange at a predetermined interval in a second direction crossing the first direction such that the following expressions (1) and (2) are satisfied:

Xi≤Xi+1 (1)

X1<Xn (2)
where Xi represents a center position coordinate of an i-th gate electrode of the gate electrodes in the first direction,
Xi+1 represents a center position coordinate of an i+1th gate electrode of the gate electrodes in the first direction, and
n represents number of the gate electrodes.

In the semiconductor device according to one embodiment of the disclosure, the plurality of gate electrodes provided one by one to each of the transistors is arranged at the predetermined interval such that the expressions (1) and (2) are satisfied. Accordingly, it is possible to eliminate heat concentration in the vicinity of the gate electrode at Xn/2, compared to the case where the plurality of gate electrodes are arranged such that Xi=Xi+1 and Xn−X1=0 are satisfied. Further, dead space is not generated unlike in a case where the plurality of gate electrodes is arranged in a zig-zag shape or V-shape.

### BRIEF DESCRIPTION OF DRAWINGS

FIG. 1 is a diagram illustrating an exemplary planar configuration of a semiconductor device according to one embodiment of the disclosure.

FIG. 2 is a diagram illustrating an exemplary cross-sectional configuration in a region a of the semiconductor device illustrated in FIG. 1.

FIG. 3 is a diagram illustrating an exemplary cross-sectional configuration in a region ß of the semiconductor device illustrated in FIG. 1.

FIG. 4 is a diagram illustrating an exemplary cross-sectional configuration in a region y of the semiconductor device illustrated in FIG. 1.

FIG. 5 is an enlarged view of the planar configuration of the semiconductor device illustrated in FIG. 1.

FIG. 6 is a diagram illustrating results of simulations of heat generation distribution of the semiconductor device.

FIG. 7 is a diagram illustrating a relation between the amount of change in a maximum temperature and a shift of the center position of a finger in the heat generation distribution of FIG. 6.

FIG. 8 is a diagram illustrating results of simulations of heat generation distribution in accordance with a change in the lengths and number of fingers with making the product of the lengths and the number of the fingers constant.

FIG. 9 is a diagram illustrating a heat generation distribution in a direction in which the fingers are arranged.

FIG. 10 is a diagram illustrating a relation between the amount of rise in temperature and an aspect ratio in the heat generation distribution of FIG. 8.

FIG. 11 is a diagram illustrating a planar configuration of the semiconductor device of FIG. 1 according to one modification example.

FIG. 12 is a diagram of an exemplary high frequency module to which the semiconductor device of FIG. 1 to FIG. 11 is applied.

FIG. 13 is a diagram illustrating an example of a radio communication apparatus to which the semiconductor device of FIG. 1 to FIG. 11 is applied.

### MODES FOR CARRYING OUT THE INVENTION

In the following, some embodiments of the disclosure are described in detail with reference to the drawings. The following description is a mere example of the disclosure, and the disclosure is not limited by the modes described below. In addition, the disclosure is not limited by the arrangements, dimensions, dimension ratios, and the like of components illustrated in each of the drawings. It is to be noted that the description is given in the following order.

### 1. Background

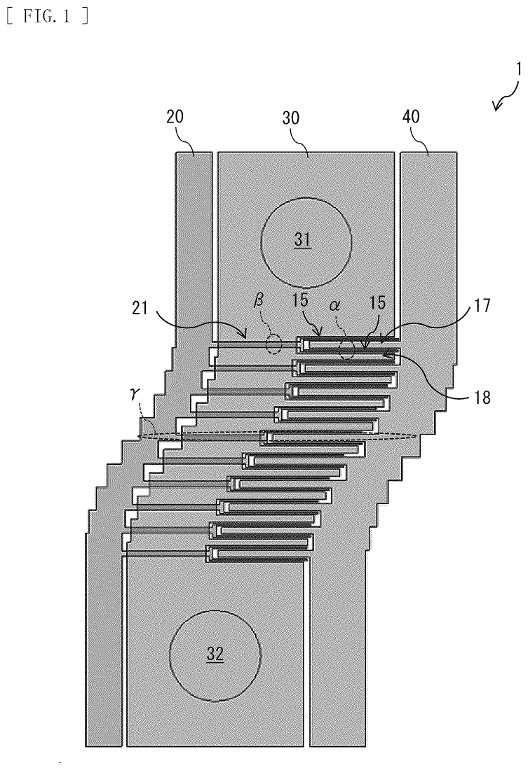

### 2. Embodiment (Semiconductor Device) . . . FIGS. 1 to 11

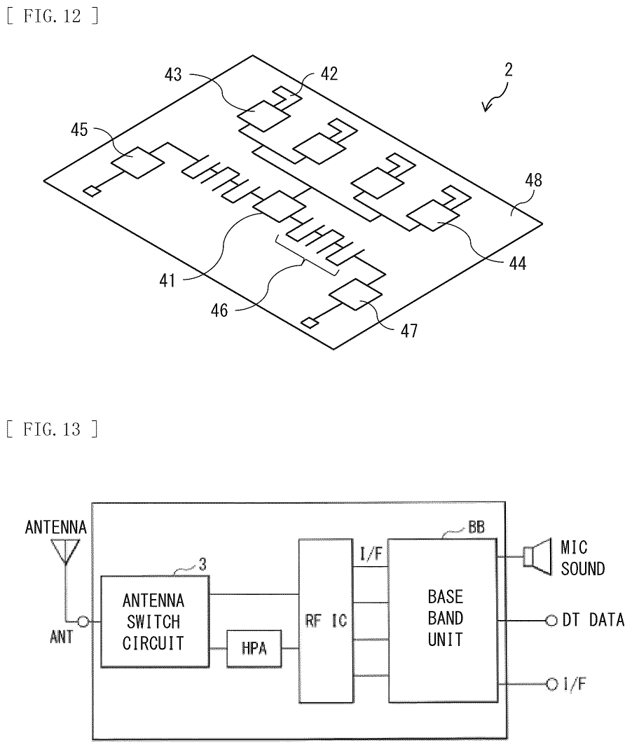

### 3. Application Examples (High Frequency Module and Radio Communication Apparatus) . . . FIGS. 12 and 13

### 1. BACKGROUND

The fifth generation (5G) mobile communication system is assumed to use signals in millimeter bands. The millimeter bands, in which spatial attenuation is large, require high-power output, resulting in the need for high-power, high-frequency semiconductor devices. Examples of the high-power, high-frequency semiconductor devices include power amplifiers and RF switches.

GaN is characterized by high breakdown voltage, high-temperature operation, and high saturation drift. A two-dimensional electron gas (2 DEG) formed at GaN heterojunctions is characterized by high mobility and high sheet-electron density. Thanks to these features, high electron mobility transistors (HEMT) using GaN-based heterojunctions are able to achieve high-speed, high-breakdown-voltage operations with low resistivity. Therefore, the high electron mobility transistors using GaN-based heterojunctions are expected to be applied to high-power, high-frequency semiconducting devices.

Incidentally, a power amplifier, in which a large current flows through a channel, has problems of heat generation due to Joule heat. As the temperature of a channel increases, the electrical resistance of the channel and the peripheral wiring line increase, resulting in deterioration in characteristics of the power amplifier. As a method of suppressing the rise in temperature of the channel, it is conceivable to promote heat exhaust to the outside of the device. However, for a portable terminal expected to include a GaN-based HEMT, the constraint of the size is large, and it is difficult to provide a sufficient heat exhaust mechanism.

As another method of suppressing the rise in temperature of the channel, it is also effective to reduce the density of the channel. Field-effect transistors (FET) for power amplifiers often employ a multi-finger structure in which multiple gates are arranged in parallel. If the total gate width is constant, reducing the gate width per one, and increasing the number of fingers make it possible to suppress the concentration of heat generation and reduce the maximum temperature. In addition, increasing the interval between the fingers makes it possible to further reduce the maximum temperature.

Meanwhile, when the array of fingers is made into a zigzag or V-shape as described in PTLs 1 and 2, a semi-closed region surrounded by the fingers becomes a dead space. Such dead space reduces the degree of freedom of the circuit layout, hindering a reduction in size. Thus, in the following, descriptions are given of some embodiments of a semiconductor device with a multi-finger structure that makes it possible to suppress the concentration of heat generation while suppressing an increase in size without reducing the degree of freedom of the circuit layout.

### 2. EMBODIMENT

### [Configuration]

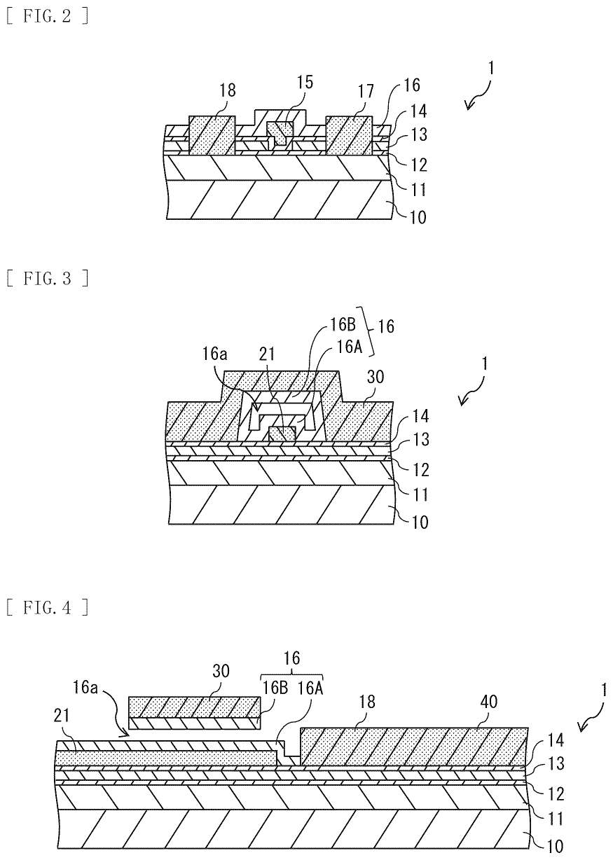

Next, a description is given of a semiconductor device 1 according to an embodiment of the disclosure. FIG. 1 illustrates an exemplary planar configuration of the semiconductor device 1 according to the present embodiment. FIG. 2 illustrates an exemplary cross-sectional configuration in a region a of the semiconductor device 1 illustrated in FIG. 1. FIG. 3 illustrates an exemplary cross-sectional configuration in a region B of the semiconductor device 1 illustrated in FIG. 1. FIG. 4 illustrates an exemplary cross-sectional configuration in a region y of the semiconductor device 1 illustrated in FIG. 1.

The semiconductor device 1 includes multiple high electron mobility transistors using heterojunctions of Al1xyGaxInyN (0≤x<1, 0≤y<1)/GaN. The semiconductor device 1 has a multi-finger structure in which the multiple high electron mobility transistors are coupled in parallel. Each of the high electron mobility transistors includes a gate electrode 15, a source electrode 17, and a drain electrode 18. The semiconductor device 1 includes, for example, a gate coupling part 20, a source coupling part 30, and a drain coupling part 40. The multiple gate electrodes 15 provided one by one to each of the high electron mobility transistors are coupled to the gate coupling part 20. The multiple source electrodes 17 provided one by one to each of the high electron mobility transistors are coupled to the source coupling part 30. The multiple drain electrodes 18 provided one by one to each of the high electron mobility transistors are coupled to the drain coupling part 40.

The gate coupling part 20 is electrically coupled to an input circuit that transmits high-frequency signals, for example. The high-frequency signals outputted from the input circuit are received by the gate electrode 15 of each of the high electron mobility transistors via the gate coupling part 20. The drain coupling part 40 is electrically coupled to an output circuit that transmits high-frequency signals, for example. The high-frequency signals outputted from the drain electrode 18 of each of the high electron mobility transistors are received by the output circuit via the drain coupling part 40. To the source coupling part 30, two via conductors (bumps) 31 and 32 are electrically coupled, for example. The via conductors 31 and 32 extend in a normal direction of a substrate 10 to be described later, and are coupled to a ground line, for example. The via conductors 31 and 32 are disposed such that the multiple high electron mobility transistors are interposed therebetween, for example.

In each of the high electron mobility transistors, the gate electrode 15, the source electrode 17, and the drain electrode 18 extend in a first direction (a horizontal direction of the page of FIG. 1). Further, the source electrode 17 and the drain electrode 18 are disposed opposite to each other in a second direction (a vertical direction of the page of FIG. 1) perpendicular to the first direction with the gate electrode 15 interposed therebetween, for example.

The gate electrode 15 include a gate operation part in contact with a channel layer 11 via a gate insulating film 14 and a barrier layer 12. When a predetermined voltage is applied to the gate electrode 15, the gate operation part controls a current flowing in a part of the channel layer 11 immediately below the gate operation part. The part of the channel layer 11 immediately below the gate operation part is an active region. In the active region, a two-dimensional electron gas layer serving as a channel is generated.

The semiconductor device 1 includes the channel layer 11 and a barrier layer 12 that are provided on the substrate 10, for example. The semiconductor device 1 further includes the insulating layer 13 and the gate insulating film 14 that are provided on the barrier layer 12, for example. The insulating layer 13 has an opening (hereinafter referred to as a “gate opening”) at a portion where the gate operation part described above is formed. The gate insulating film 14 is formed in contact with a part of the barrier layer 12 exposed at a bottom surface of the gate opening of the barrier layer 12. The gate insulating film 14 is a conformal layer formed in conformance to the bottom surface and the inner wall of the barrier layer 12 and a surface of the insulating layer 13. The semiconductor device 1 further includes the gate electrode 15 formed so as to fill the gate opening of the barrier layer 12.

The barrier layer 12 has a pair of openings (hereinafter referred to as a “source opening” and a “drain opening”) in addition to the gate opening. The source opening and the drain opening are disposed at respective positions opposite to each other with the gate opening interposed therebetween, and extend in the first direction (the horizontal direction of the page of FIG. 1). The channel layer 11 is exposed at bottom surfaces of the source opening and the drain opening.

The semiconductor device 1 further includes, for example, the source electrode 17 and the drain electrode 18. The source electrode 17 is in ohmic junction with the channel layer 11 exposed at the bottom surface of the source opening. The drain electrode 18 is in ohmic junction with the channel layer 11 exposed at the bottom surface of the drain opening. The semiconductor device 1 further includes, for example, the gate electrode 15 and the insulating layer 16 formed in contact with the surface of the gate insulating film 14. The insulating layer 13, the gate insulating film 14, and the insulating layer 16 each have openings in a pair of regions that sandwich the gate electrode 15. The openings of the insulating layer 13, the gate insulating film 14, and the insulating layer 16 in one of the paired regions is filled with the source electrode 17. The openings of the insulating layer 13, the gate insulating film 14, and the insulating layer 16 in the other region of the paired regions is filled with the drain electrode 18. Upper surfaces of the source electrode 17 and the drain electrode 18 are exposed on a surface of the insulating layer 16.

The substrate 10 includes GaN, for example. In a case where a buffer layer that controls a lattice parameter is provided between the substrate 10 and the channel layer 11, the substrate 10 may include, for example, Si, SiC, or sapphire. In this case, the buffer layer includes, for example, a compound semiconductor such as AlN, AlGaN, or GaN.

The channel layer 11 is a layer in which channels of the high electron mobility transistors are formed. The active region (channel region) of the channel layer 11 is a region in which carriers are accumulated due to polarization from the barrier layer 12. The channel layer 11 is formed using a compound semiconductor material in which carriers are easily accumulated due to polarization from the barrier layer 12. Examples of the compound semiconductor material include GaN. The channel layer 11 may be formed using an undoped compound semiconductor material. In such a case, impurity scattering of carriers in the channel layer 11 is suppressed, and carrier mobility at a high rate is achieved. When the channel layer 11 and the barrier layer 12 that are formed using different compound semiconductors are in heterojunction to each other, the two-dimensional electron gas layer serving as a channel is formed at an interface of the channel layer 11 in contact with the barrier layer 12.

The barrier layer 12 is formed using a compound semiconductor material so that carriers are accumulated in the channel layer 11 due to polarization from the channel layer 11. Examples of the compound semiconductor material include Al1abGaaInbN (0≤a<1, 0≤b<1). The barrier layer 12 may be formed using an undoped compound semiconductor material. In such a case, impurity scattering of carriers in the channel layer 23 is suppressed, and carrier mobility at a high rate is achieved. It is to be noted that a spacer layer including, for example, AlN may be provided between the barrier layer 12 and the channel layer 11 to control the heterojunction interface, for example. The channel layer 11, the barrier layer 12, and the spacer layer may be formed by metal organic chemical vapor deposition (MOCVD) or molecular beam epitaxy (MBE), for example.

The insulating layer 13, the gate insulating film 14, and the insulating layer 16 are each formed using aluminum oxide (Al₂O₃), silicon oxide (SiO₂), or silicon nitride (SiN). The gate electrode 15 has a structure in which nickel (Ni) and gold (Au) are stacked in this order from the substrate 10, for example. The source electrode 17 and the drain electrode 18 in ohmic junction with the channel layer 11 each have a structure in which titanium (Ti), aluminum (Al), nickel (Ni), and gold (Au) are stacked in this order from the substrate 10, for example.

As illustrated in FIG. 1, for example, the gate coupling part 20 has multiple branches 21 provided one by one to each pair of the gate electrodes 15 of two high electron mobility transistors. One end of each of the branches 21 is coupled to the gate electrodes 15 of the two high electron mobility transistors. A plurality of voids 16a may be formed in the insulating layer 16. In this case, as illustrated in FIG. 3, for example, each of the plurality of voids 16a is provided at a portion opposite to the branch 21. As illustrated in FIG. 4, for example, each of the voids 16a may be communicated with the outside. In this case, as illustrated in FIG. 4, for example, the insulating layer 16 includes an insulating layer 16A in contact with an upper face of the branch 21 and an insulating layer 16B in contact with a rear face of the source coupling part 30. The void 16a is formed between the insulating layer 16A and the insulating layer 16B. The source coupling part 30 is formed so as to extend across the plurality of voids 16a.

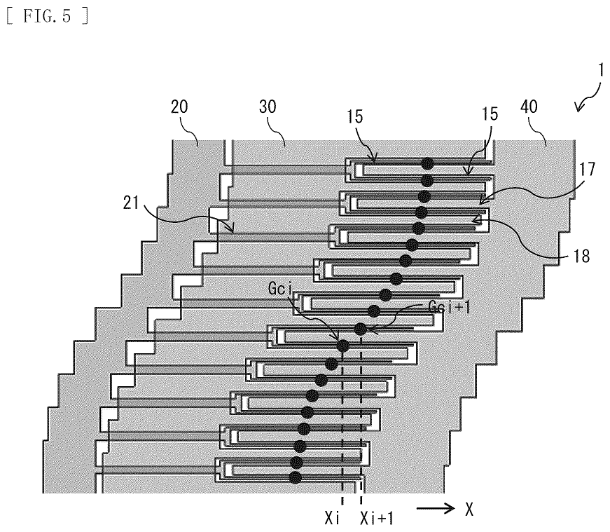

FIG. 5 illustrates a portion of the planar configuration illustrated in FIG. 1 in an enlarge manner. In FIG. 5, a plot is given to a central position Gci in a longitudinal direction of an i-th gate electrode 15 (where 1≤I≤n−1, n is the number of the gate electrodes 15) from the bottom of the page. In addition, in FIG. 5, a plot is given to a central position Gci+1 in the longitudinal direction of an i+1-th gate electrode 15 from the bottom of the page.

The multiple gate electrodes 15 of the semiconductor device 1 may have a length equal to each other. It is to be noted that at least some (one or more) of the multiple gate electrodes 15 of the semiconductor device 1 may have a length different from the other gate electrodes 15.

In the semiconductor device 1, the multiple gate electrodes 15 are arranged at a predetermined interval in the second direction. For example, the multiple gate electrodes 15 are arranged at an equal interval in the second direction (the vertical direction of the page of FIG. 5). An arrange pitch of the multiple gate electrodes 15 in the second direction may be constant regardless of locations or may be different depending on locations. The multiple gate electrodes 15 in the semiconductor device 1 are arranged such that center positions Gci satisfy the following expressions (1) and (2):

Xi≤Xi+1 (1)

X1<Xn (2)
where Xi represents a center position coordinate of an i-th gate electrode 15 in the first direction,
Xi+1 represents a center position coordinate of an i+1th gate electrode 15 in the first direction, and
n represents the number of the gate electrodes 15.

In this case, the multiple gate electrodes 15 in the semiconductor device 1 may be arranged such that the center positions Gci satisfy the following expression (3):

Xi<Xi+1 (3)

Alternatively, the multiple gate electrode 15 in the semiconductor device 1 may be arranged such that Xi+1−Xi takes the largest value when i is n/2 or nearly n/2. In this case, the multiple gate electrodes 15 in the semiconductor device 1 are preferably arranged such that Xi+1−Xi gradually increases as i changes from 1 toward n/2. Further, the multiple gate electrode 15 in the semiconductor device 1 are preferably arranged such that Xi+1−Xi gradually increases as i changes from n toward n/2. In this case, the center positions Gci are arranged into an S-shape. In the following, such an arrangement of the multiple gate electrodes 15 is referred to as an “S-shape type 2”.

In the “S-shape type 2”, Xn−X1 may be equal to or greater than a longitudinal length of the gate electrode 15 (e.g., the length of the gate electrode 15 having the largest length among the multiple gate electrodes 15). In addition, in the “S-shape type 2”, a curved line obtained by connecting the center positions Gci of the gate electrodes 15 may have a length three times or greater than the longitudinal length of the gate electrode 15 (e.g., the length of the gate electrode 15 having the largest length among the multiple gate electrodes 15).

It is to be noted that, also when the multiple gate electrodes 15 in the semiconductor device 1 are arranged such that Xi+1−Xi gradually decreases as i changes from 1 toward n/2, and that Xi+1−Xi gradually decreases as i changes from n toward n/2, the center positions Gci are arranged in an S-shape. Note that, in the following, such an arrangement of the multiple gate electrodes 15 is referred to as an “S-shape type 1”. In addition, in the following, such an arrangement of the multiple gate electrodes 15 in the semiconductor device 1 that Xi+1−Xi is constant regardless of locations is referred to as a “linear type”. It is to be noted that the term “linear” in the “linear type” refers to a straight line parallel to the second direction when Xi+1−Xi is zero, and refers to a straight line that extends in a direction crossing the second direction when Xi+1−Xi takes a positive or negative value.

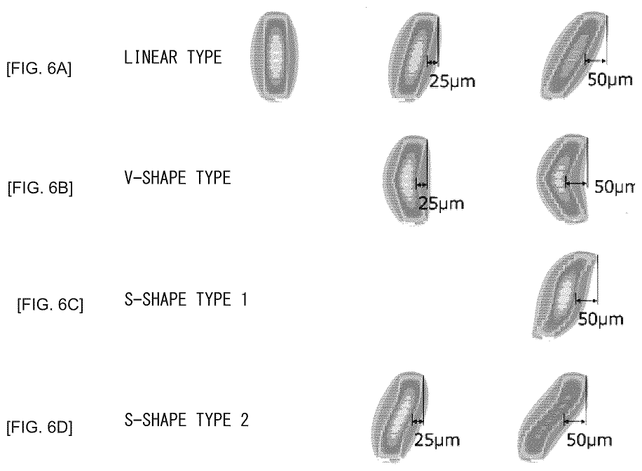

FIG. 6 illustrates results of simulations of heat generation distributions of semiconductor devices according to Examples and Comparative Examples. The heat generation distribution on the leftmost side of FIG. 6(A) illustrates the result of the simulation in which the multiple gate electrodes 15 were arranged such that Xi=Xi+1 was satisfied. The heat generation distribution in the middle of FIG. 6(A) illustrates the result of the simulation in which the multiple gate electrodes 15 were arranged such that Xi+1−Xi took a positive constant and that Xn−X1 become 25 μm. The heat generation distribution on the rightmost side of FIG. 6(A) illustrates the result of the simulation in which the multiple gate electrodes 15 were arranged such that Xi+1−Xi took a positive constant and that Xn−X1 become 50 μm.

Two heat generation distributions in FIG. 6(B) illustrate the results of simulations in which the multiple gate electrodes 15 were arranged such that Xi+1−Xi took a negative constant when 1≤i≤n/2 was satisfied and that Xi+1−Xi took a positive constant when n/2≤i≤n was satisfied. The heat generation distribution in the middle of FIG. 6(B) illustrates the result of the simulation in which the multiple gate electrodes 15 were arranged such that Xn−Xn/2 become 25 μm. The heat generation distribution on the right most side of FIG. 6(B) illustrates the result of the simulation in which the multiple gate electrodes 15 were arranged such that Xn−Xn/2 become 50 μm.

The heat generation distribution in FIG. 6(C) illustrates the result of the simulation in which the multiple gate electrodes 15 were arranged in the “S-shape type 1”. The heat generation distributions in FIG. 6(D) illustrate the results of the simulations in which the multiple gate electrodes 15 were arranged in the “S-shape type 2”. The heat generation distribution in the middle of FIG. 6(D) illustrates the result of the simulation in which the multiple gate electrodes 15 were arranged such that Xn−Xn/2 become 25 μm. The heat generation distribution on the rightmost side of FIG. 6(D) illustrates the result of the simulation in which the multiple gate electrodes 15 were arranged such that Xn−Xn/2 become 50 μm.

It is to be noted that, in the semiconductor device 1 having the heat generation distribution illustrated in FIG. 6(D), Xn−X1 is a length equal to or greater than the longitudinal length of the gate electrode 15 (e.g., the length of the gate electrode 15 having the largest length among the gate electrode 15 of the multiple gate electrodes 15). In addition, in the semiconductor device 1 having the heat generation distribution illustrated in FIG. 6(D), a curved line obtained by connecting the center positions Gci of the gate electrodes 15 has a length three times or greater than the longitudinal length of the gate electrode 15 (e.g., the length of the gate electrode 15 having the largest length among the gate electrode 15 of the multiple gate electrodes 15).

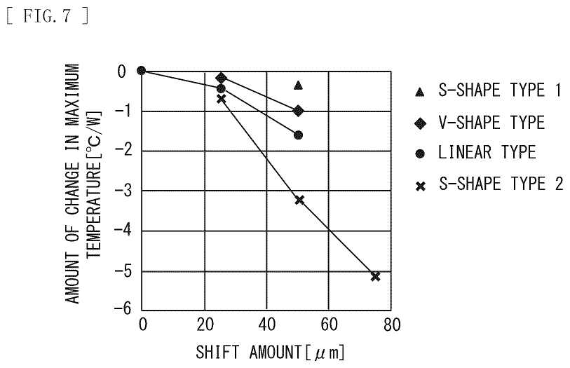

FIG. 7 collectively illustrates the results illustrated in FIG. 6. In FIG. 7, a vertical axis represents a value obtained by dividing a difference between a maximum temperature (reference temperature) of the temperature distribution in the simulation illustrated in the leftmost of FIG. 6(A) and a maximum temperature in the result of each simulation by a total heat generation volume. In FIG. 7, a horizontal axis represents Xn−Xn/2 (a shift amount).

It is apparent from FIGS. 6 and 7 that the maximum temperature decreased as the shift amount increased, and that S-shape type 2 was the arrangement that exhibited the highest heat dissipation effect when the shift amount was the same. It is also apparent that S-shape type 1 and V-shape type are inferior to S-shape type 2 in heat dissipation. From the facts described above, it is apparent that heat concentration in the vicinity of the gate electrode 15 at Xn/2 is effectively eliminated as the shift amount in the vicinity of the gate electrode 15 at Xn/2 increases.

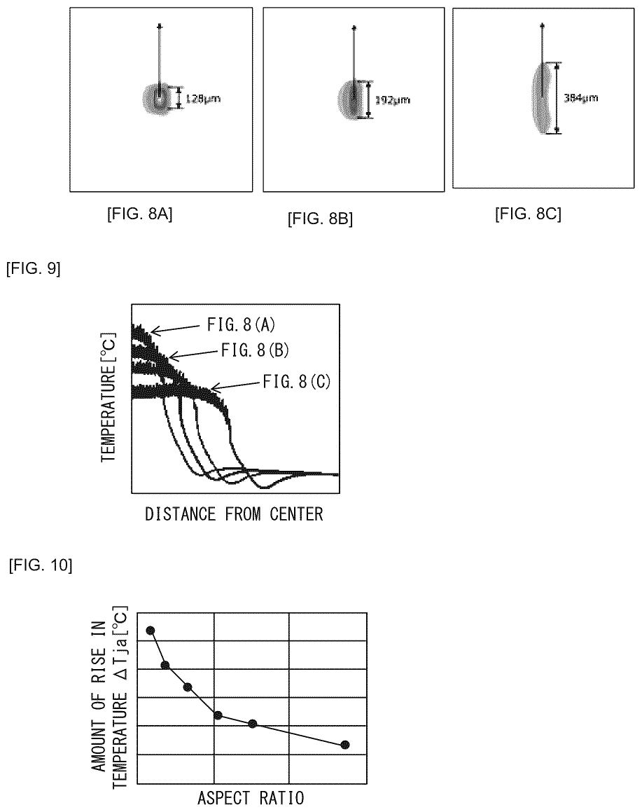

FIG. 8(A), FIG. 8(B), FIG. 8(C) illustrate results of simulations of heat generation distributions in accordance with a change in the lengths and number of fingers with making the product of the lengths and the number of the gate electrodes 15 constant. FIG. 8(A) illustrates the result of the simulation in which the length of each gate electrode 15 was set to be 75 μm and the number of the gate electrodes 15 was set to be 20. FIG. 8(B) illustrates the result of the simulation in which the length of each gate electrode 15 was set to be 50 μm and the number of the gate electrodes 15 was set to be 30. FIG. 8(C) illustrates the result of the simulation in which the length of each gate electrode 15 was set to be 25 μm and the number of the gate electrodes 15 was set to 60. FIG. 9 is a waveform chart of the heat generation distributions of FIG. 8(A), FIG. 8(B), and FIG. 8(C) in an arrangement direction of the gate electrodes 15. It is apparent from FIG. 9 that the maximum temperature decreased and the temperature distribution approached homogeneity as the number of the gate electrodes 15 increased. One reason for this is supposed that the heat dissipation was facilitated as the distance between the position having the maximum temperature and an outside area of the region in which the multiple gate electrodes 15 were arranged become short with an increase in the number of the gate electrodes 15.

FIG. 9 illustrates a relation between an aspect ratio of the region in which the multiple gate electrodes 15 are arranged and the amount of rise in temperature ΔTja [° C.] from the ambient temperature. It is apparent from FIG. 9 that the maximum temperature decreased and the temperature distribution approached homogeneity as the aspect ratio of the region in which the multiple gate electrodes 15 were arranged increased. One reason for this is supposed that the heat dissipation was facilitated as the distance between the position having the maximum temperature and the outside area of the region in which the multiple gate electrodes 15 were arranged become short with an increase in the aspect ratio of the arrange region.

### [Effects]

Next, effects of the semiconductor device 1 are described.

According to the present embodiment, when a predetermined voltage is applied to the gate electrode 15, the two-dimensional electron gas layer is generated in a portion of the channel layer 11 immediately below the gate electrode 15. The portion of the channel layer 11 immediately below the gate electrode 15 is thus serve as an active region (channel region). As a result, an electric current flows from the drain electrode 18 through the active region (channel region) of the channel layer 11 to the source electrode 17. Accordingly, the portion of the channel layer 11 immediately below the gate electrode 15 operates as a general HEMT.

In this case, the electric current flowing in the channel layer 11 generates heat. The generated heat is released to outside through the substrate 10, the source electrode 17, and the drain electrode 18. However, the heat generated locally is likely to remain inside the semiconductor device 1. This can increase a temperature of the channel and electric resistance of the cannel and peripheral wiring lines, resulting in deterioration of a device characteristic.

However, in the present embodiment, the multiple gate electrodes 15 that are provided one by one to each of the high electron mobility transistors are arranged at the predetermined interval so that the expressions (1) and (2) are satisfied. Accordingly, it is possible to eliminate heat concentration in the vicinity of the gate electrode at Xn/2, compared to the case where the multiple gate electrodes 15 are arranged so that Xi=Xi+1 and Xn−X1=0 are satisfied. Further, dead space is not generated unlike in a case where the multiple gate electrodes 15 are arranged in a zig-zag shape or V-shape. Accordingly, the semiconductor device 1 having the multi-finger structure makes it possible to suppress an increase in size and suppress heat concentration without decreasing the degree of freedom of the circuit layout.

Further, in the present embodiment, the multiple gate electrodes 15 may have a length equal to each other. This simplifies the formation of the multi-finger structure. As a result, it is possible to suppress an increase in size and further suppress heat generation without decreasing the degree of freedom of the circuit layout.

Further, in the present embodiment, the multiple gate electrodes 15 may be arranged so that Xi+1−Xi takes a positive or negative value that is constant regardless of locations. This also simplifies the formation of the multi-finger structure. As a result, it is possible to suppress an increase in size and further suppress heat generation without decreasing the degree of freedom of the circuit layout.

Further, in the present embodiment, the multiple gate electrodes 15 may be arranged so that Xi+1−Xi takes the largest value when i is n/2 or nearly n/2. This makes it possible to effectively eliminate heat concentration in the vicinity of the gate electrode at Xn/2.

Further, in the present embodiment, the multiple gate electrodes 15 may be arranged so that Xi+1−Xi gradually increases as i changes from 1 to n/2, and that Xi+1−Xi gradually increases as i changes from n to n/2. This makes it possible to effectively eliminate heat concentration in the vicinity of the gate electrode at Xn/2.

Further, in the present embodiment, Xn−X1 may be equal to or greater than the length of the gate electrode 15 in the first direction. This makes it possible to effectively eliminate heat concentration in the vicinity of the gate electrode at Xn/2.

Further, in the present embodiment, the length of the curved line obtained by connecting the center positions of the gate electrodes 15 may be three times or greater than the length of the gate electrode in the first direction. This makes it possible to effectively eliminate heat concentration in the vicinity of the gate electrode at Xn/2.

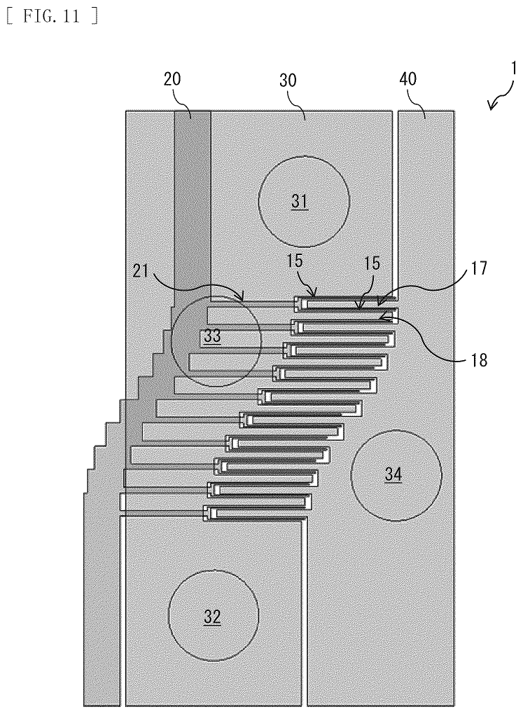

It is to be noted that, in the foregoing embodiment, via conductors (bumps) 33 and 34 may be further provided as illustrated in FIG. 11, for example. The via conductor 33 is in contact with a portion of the source coupling part 30 immediately above the multiple branches 21. The via conductor 34 is in contact with a portion of the drain coupling part 40 opposed to the multiple branches 21 with the multiple gate electrodes 15 interposed therebetween. That is, the via conductors 34 and 34 are opposed to each other with the multiple gate electrodes 15 interposed therebetween. This makes it possible to effectively release the heat generated at the channel to outside through the via conductors 33 and 34.

It is to be noted that the interval between two adjacent gate electrodes 15 in the foregoing embodiment may have a rectangular shape or a fan shape.

### 3. APPLICATION EXAMPLES

### Application Example 1

Next, a high frequency module 2 to which the semiconductor device 1 according to the embodiment or the modification example of the disclosure is applied is described with reference to FIG. 12. FIG. 12 is a perspective view of the high frequency module 2.

The high frequency module 2 includes, for example, edge antennas 42, drivers 43, phase adjustment circuits 44, a switch 41, a low noise amplifier 45, a band-pass filter 46, and a power amplifier 47.

The high frequency module 2 is an antenna integrated type module in which front-end components, such as the edge antennas 42 formed in an array, the switch 41, the low noise amplifier 45, the band-pass filter 46, and the power amplifier 47, that are integrated as one module is mounted. The high frequency module 2 may be used as a communication transceiver, for example. Transistors of the switch 41, the low noise amplifier 45, the power amplifier 47, and the like included in the high frequency module 2 may be, for example, the high electron mobility transistors provided in the semiconductor device 1 according to the embodiment or the modification example of the disclosure in order to increase a high frequency gain.

### Application Example 2

FIG. 13 illustrates an example of a radio communication apparatus. The radio communication apparatus is, for example, a portable phone system with multiple functions such as sound communication, data communication, and LAN connection. The radio communication apparatus includes, for example, an antenna ANT, an antenna switch circuit 3, a high power amplifier HPA, a radio frequency integrated circuit (RFIC), a base band BB, a sound output unit MIC, a data output unit DT, and an interface unit I/F (e.g., wireless local area network (W-LAN)), Bluetooth (registered trademark), or the like). The antenna switch circuit 3 includes the high electron mobility transistors provided in the semiconductor device 1 according to the embodiment and the modification example of the disclosure. The radio frequency integrated circuit RFIC and the base band BB are coupled to each other with the interface unit I/F.

Upon transmission, that is, when a transmission signal is sent from a transmission system of the radio communication apparatus to the antenna ANT, the transmission signal outputted from the base band BB is outputted to the antenna ANT via the radio frequency integrated circuit RFIC, the high power amplifier HPA, and the antenna switch circuit 3.

Upon reception, that is, when the signal received at the antenna ANT is inputted to a receiving system of the radio communication apparatus, the received signal is inputted to the base band BB via the antenna switch circuit 3 and the radio frequency integrated circuit RFIC. The signal processed at the base band BB is outputted from output units such as the sound output unit MIC, the data output unit DT, or the interface I/F.

Although the disclosure has been described with reference to the embodiments, the modification examples, and the application examples, the disclosure should not be limited to the embodiments and the like described above, and various modifications may be made. It is to be noted that the effects described herein are mere examples, and effects of the disclosure should not be limited to the effects described herein. The disclosure may have effects other than the effects described herein.

Further, the disclosure may have the following configurations, for example.
(1) A semiconductor device including:
   multiple transistors coupled in parallel to each other, in which
   each of the transistors includes a gate electrode, a source electrode, and a drain electrode that extend in a first direction,
   a plurality of the gate electrodes provided one by one to each of the transistors is arranged at a predetermined interval in a second direction crossing the first direction, and
   the plurality of the gate electrodes is arranged such that the following expressions (A) and (B) are satisfied:

Xi≤Xi+1 (A)

X1<Xn (B)
where Xi represents a center position coordinate of an i-th gate electrode of the gate electrodes in the first direction,
Xi+1 represents a center position coordinate of an i+1th gate electrode of the gate electrodes in the first direction, and
n represents number of the gate electrodes.
(2) The semiconductor device according to (1), in which the plurality of the gate electrodes has a length equal to each other.
(3) The semiconductor device according to (1) or (2), in which the plurality of the gate electrodes is arranged such that Xi+1−Xi takes a positive or negative value that is constant regardless of locations.
(4) The semiconductor device according to any one of (1) to (3), in which the plurality of the gate electrodes is arranged such that Xi+1−Xi takes a largest value when i is n/2 or nearly n/2.
(5) The semiconductor device according to (4), in which the plurality of the gate electrodes is arranged such that Xi+1−Xi gradually increases as i changes from 1 to n/2 and that Xi+1−Xi gradually increases as i changes from n to n/2.
(6) The semiconductor device according to (4), in which Xn−X1 is a length equal to or greater than a length of the gate electrode in the first direction.
(7) The semiconductor device according to (4), in which a curved line obtained by connecting center positions of the gate electrodes has a length three times or greater than the gate electrode in the first direction.
(8) The semiconductor device according to any one of (1) to (7), including:
   a gate coupling part electrically coupled to the plurality of the gate electrodes;
   a source coupling part electrically coupled to a plurality of the source electrodes;
   a drain coupling part electrically coupled to a plurality of the drain electrodes;
   a first via in contact with the gate coupling part; and
   a second via in contact with the drain coupling part, in which
   the first via and the second via are disposed opposite to each other with the plurality of the gate electrodes interposed therebetween.

This application claims the benefit of Japanese Priority Patent Application JP2021-064449 filed with the Japan Patent Office on Apr. 5, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A semiconductor device comprising
multiple transistors coupled in parallel to each other, wherein
each of the transistors includes a gate electrode, a source electrode, and a drain electrode that extend in a first direction,
a plurality of the gate electrodes provided one by one to each of the transistors are arranged at a predetermined interval in a second direction crossing the first direction such that the following expressions (1) and (2) are satisfied:
Xi≤Xi+1 (1)
X1<Xn (2)
where Xi represents a center position coordinate of an i-th gate electrode of the gate electrodes in the first direction,
Xi+1 represents a center position coordinate of an i+1th gate electrode of the gate electrodes in the first direction, and
n represents number of the gate electrodes.

2. The semiconductor device according to claim 1, wherein the plurality of the gate electrodes has a length equal to each other.

3. The semiconductor device according to claim 1, wherein the plurality of the gate electrodes is arranged such that Xi+1−Xi takes a positive or negative value that is constant regardless of locations.

4. The semiconductor device according to claim 1, wherein the plurality of the gate electrodes is arranged such that Xi+1−Xi takes a largest value when i is n/2 or nearly n/2.

5. The semiconductor device according to claim 4, wherein the plurality of the gate electrodes is arranged such that Xi+1−Xi gradually increases as i changes from 1 to n/2 and that Xi+1−Xi gradually increases as i changes from n to n/2.

6. The semiconductor device according to claim 4, wherein Xn−X1 is a length equal to or greater than a length of the gate electrode in the first direction.

7. The semiconductor device according to claim 4, wherein a curved line obtained by connecting center positions of the gate electrodes has a length three times or greater than the gate electrode in the first direction.

8. The semiconductor device according to claim 1, comprising:
a gate coupling part electrically coupled to the plurality of the gate electrodes;
a source coupling part electrically coupled to a plurality of the source electrodes;
a drain coupling part electrically coupled to a plurality of the drain electrodes;
a first via in contact with the gate coupling part; and
a second via in contact with the drain coupling part, wherein
the first via and the second via are disposed opposite to each other with the plurality of the gate electrodes interposed therebetween.
